(19) United States
(12) Patent Application Publication
(10) Pub. No.: US 2021/0193401 A1
(43) Pub. Date: Jun. 24, 2021

(54) SUPERCAPACITOR WITH BOTH CURRENT COLLECTOR AND ELECTRODE BASED ON TRANSITION METAL NITRIDE AND THE PREPARATION METHOD THEREFOR

(71) Applicant: DALIAN UNIVERSITY OF TECHNOLOGY, Dalian, Liaoning (CN)

(72) Inventors: Dayu ZHOU, Dalian, Liaoning (CN); Nana SUN, Dalian, Liaoning (CN); Wenwen LIU, Dalian, Liaoning (CN); Shuyan SHI, Dalian, Liaoning (CN); Fengyun YU, Dalian, Liaoning (CN); Xiaoduo HOU, Dalian, Liaoning (CN); Xiaoxia GAO, Dalian, Liaoning (CN)

(21) Appl. No.: 16/980,278

(22) PCT Filed: Nov. 13, 2019
(86) PCT No.: PCT/CN2019/118045

§ 371 Date: Sep. 11, 2020

(30) Foreign Application Priority Data
Jan. 22, 2019 (CN) 201910056547.6
Jan. 22, 2019 (CN) 201910056548.0
Jan. 22, 2019 (CN) 201910060755.3

(51) Int. Cl. H01G 11/86; H01G 11/30; H01G 11/68; C23C 14/34; C23C 14/06; C23C 16/06

(52) U.S. Cl. CPC H01G 11/86; H01G 11/30; C23C 16/06; C23C 14/34; C23C 14/0641; H01G 11/68

(57) ABSTRACT

A supercapacitor with both current collector and electrode based on transition metal nitride and the preparation method therefor is disclosed. First, the substrates were subjected to a standard cleaning technique to remove impurities and contaminations on the surface; then a layer of transition metal nitride film with high density and conductivity was deposited on the surface of substrates as a current collector to transport electrons. By simply adjusting the deposition process parameters, a rough and porous transition metal nitride film with high resistivity was grown directly on the current collector as active electrode material. In this invention, the transition metal nitrides were grown continuously as the current collector and then as the electrode materials, and the properties of these two materials can be tailored easily by changing the deposition process parameters.

### TECHNICAL FIELD

The present invention belongs to the technical field of electronic functional materials and devices, which is related to a supercapacitor with both current collector and electrode based on transition metal nitride and the preparation method therefor.

### BACKGROUND

As a new type of green electrical energy storage device, supercapacitors have attracted tremendous attention, owing to their significant advantages of high energy and power densities, long charge/discharge cycling life, a wide range of operating temperature, maintenance-free, environmental friendship and so on. Recently, the research and application of various sensor systems in the wireless internet of things and wearable as well as implantable medical devices are growing very fast. These low-power electronic devices have put forward the development of supercapacitors with critical requirements of miniaturization and lightweight, fabrication by thin film technology, and even complete monolithic integration with other electronic components. Supercapacitors mainly consist of electrodes, current collectors and electrolytes. Among them, electrodes and current collectors play important roles that determine the performance of supercapacitors. At present, the electrode materials used for supercapacitors mainly include carbon-/silicon-based materials, metal oxides, conductive polymers and so on. These materials are normally deposited directly on or coated on the metal collectors (e.g., gold, copper or nickel foam etc.) after mixing with conductive and adhesive agents. The function of the electrodes material is to store and release charges based on the electric double layer or/and pseudocapacitance effects. And the function of the current collector is to transport electrons and connect the external charge/discharge circuits. The usages of different types of materials in electrodes and current collectors cause poor adhesion, delamination and cracking due to their lattice mismatch and difference in the thermal expansion coefficients, leading to large contact resistance. These issues severely limit the performance improvement of supercapacitors such as power density, thermal stability and long-term service reliability. The transition metal nitride films exhibit excellent physical and chemical properties such as high melting point and hardness, excellent wear resistance, and high oxidation as well as corrosion resistance. And especially their conductivity is adjustable in a wide range. Taking TiN as an example, the films with resistivity ranged from tens to thousands of μΩ·cm can be prepared controllably by changing the deposition process parameters to adjust the composition stoichiometry and microstructure in the films. In current microelectronic industry, highly conductive TiN and TaN thin films are most commonly used as gate electrodes of transistors and electrodes of storage capacitors in DRAM. Recently, researchers from France reported that porous TiN and VN thin films with high resistivity (ρ>1000μΩ·cm) could exhibit large specific capacitance values, which are comparable to those of the carbon-/graphene-based materials and transition metal oxides. However, in their prepared supercapacitors, the aforementioned films act bi-functionally as both the electrode material and current collector. The high resistivity of the films results in poor frequency response (rate) characteristics of the device too.

Based on the unique property of transition metal nitride films that their resistivity can be regulated flexibility, this invention provides a new type of supercapacitor and its preparation methodology. First, a highly conductive (ρ<500 μΩ·cm) transition metal nitride film was deposited on the substrate as current collector to transport electrons. Then by simply adjusting the deposition process parameters, a porous structure transition metal nitride film with high resistivity (ρ>1000μΩ·cm) was grown directly on the current collector as active electrode material. The advantages of this invention are as follows: transition metal nitrides were grown continuously as the current collector and then as the electrode materials, and the properties of these two materials can be tailored easily by changing the deposition process parameters. The preparation method is simple, easy to operate, and low cost. There are many selections of film deposition technologies, leading to good feasibility and practicality of the preparation methodology. It can solve the problems caused by lattice mismatch and difference in the thermal expansion coefficients of heterogeneous current collector and electrode materials, including poor adhesion, delamination, cracking and large contact resistance. Therefore the power density, thermal stability and long-term service reliability of the supercapacitors can be improved significantly.

### SUMMARY

The aim of the present invention is to provide a supercapacitor with both current collector and electrode based on transition metal nitride and the novel preparation method therefor. Transition metal nitrides grown continuously are used as the current collector and electrode materials, and their properties are tailored by simply changing the film deposition parameters. The method is simple, easy to operate, and low cost. There are many selections of film deposition technologies, leading to good feasibility and practicality of the preparation methodology. It provides a feasible new solution to improve the overall performance characteristics of supercapacitors including energy density, power density and reliability, etc.

In order to achieve the above objective, the technical solution of the present invention is as follows:

A supercapacitor with both current collector and electrode based on transition metal nitride, the structure of the supercapacitor can be a sandwich structure, planar interdigitated structure, or 3D nanostructure. The positive and negative terminals of the supercapacitor can be symmetrically or asymmetrically constructed. For the symmetrical structure, both the positive and negative terminals of the supercapacitor will use the same kind of transition metal nitride (abbreviated as MN) material as current collector/electrode. However for the asymmetric structure, the positive and negative terminals of the supercapacitor can use different kinds of transition metal nitrides as current collector/electrode materials. And also one terminal can use transition metal nitride (MN) material as current collector/electrode, but the other terminal can use conventional electrode and current collector materials of supercapacitors. The conventional electrode materials of supercapacitors are carbon-/silicon-based materials, metal oxides and conductive polymers, etc. The conventional current collector materials of supercapacitors include gold, copper, titanium, platinum, nickel foam, etc. The M element in the MN is Ti, V, Ta, Mo or one or more of other transition metal elements.

Furthermore, the M element is preferably V or Ti. If the M element is V, both the positive and negative terminals of the supercapacitor with symmetrical structure will use VN as current collector/electrode materials. While, for the asymmetrical structure, the positive and negative terminals of the supercapacitor will use different materials as current collectors or electrodes. One terminal will use VN as current collector/electrode, but the other terminal will use the conventional electrode and current collector materials of supercapacitors. When the M element is Ti, both the positive and negative terminals of the supercapacitor with symmetrical structure use TiN as current collector/electrode materials. While, for the asymmetrical structure, the positive and negative terminals of the supercapacitor use different materials as current collectors or electrodes. One terminal uses TiN as current collector/electrode, but the other terminal uses aforementioned conventional electrode and current collector materials of supercapacitors.

A preparation method of supercapacitors with both current collector and electrode based on transition metal nitride is provided. In this method, the substrate is first cleaned to remove the impurities and contaminations on the surface. Then a layer of transition metal nitride film with high density and conductivity is deposited on the substrate as a current collector to transport electrons. Finally, a layer of porous transition metal nitride film with low conductivity is grown directly on the current collector as an electrode. The changes in properties of films are achieved by adjusting the deposition process parameters, which affect the mechanisms of surface atom diffusion, nucleation and growth. The details of the preparation procedure are given as follows.

Step 1: The substrates are subjected to a standard cleaning technique to remove impurities and contaminations on the surface.

The substrate material is one of Si, Ge and the other III/V semiconductor materials, glass or flexible polymer substrate. The III/V semiconductors are gallium arsenide and so on. The flexible polymer substrate materials are polyethylene terephthalate (PET), polyimide (PI) and so on.

Step 2: Deposition of transition metal nitride (MN) current collectors/electrodes materials.

The traditional thin film deposition techniques will be used, and the mechanisms of surface atomic diffusion, nucleation and growth will be regulated effectively by adjusting the deposition process parameters. First, a layer of smooth MN thin film with high density and conductivity (low resistivity) will be deposited as a current collector on the cleaned substrates described in step 1. Then the deposition parameters are adjusted to tailor the mechanisms of surface atomic diffusion, nucleation and growth of the thin film, whereby a layer of rough and porous MN thin film with low conductivity (high resistivity) is grown continuously on the current collector as an electrode. As a result, MN current collector/electrode materials are deposited on the surface of the substrate.

The thickness of the MN thin film for the current collector is 10-5000 nm, with the resistivity less than 500 μΩ·cm.

The thickness of the MN thin film for the electrode is 10-5000 nm, with the resistivity higher than 1000 μΩ·cm.

The deposition process parameters include the distance between the target and substrate, the ratio of argon to nitrogen, sputtering power, substrate temperature, working pressure, bias voltage applied on substrate and so on.

The details of process parameters for deposition of current collector are as follows: the distance between the target and substrate in the range of 10-100 mm; Ar:N₂=(10-60):(1-10) sccm; the sputtering power in the range of 100-400 W; the substrate temperature ranged from room temperature to 400° C.; the working pressure in the range of 0.2-1.5 Pa; the bias voltage applied on substrate ranged from −50 to −400 V; and the sputtering time in the range of 1-500 min.

The details of process parameters for deposition of electrode are as follows: the distance between the target and substrate in the range of 10-100 mm; Ar:N₂=(10-60):(1-10) sccm; the sputtering power in the range of 100-400 W; the substrate temperature ranged from room temperature to 400° C.; the working pressure in the range of 0.4-1.5 Pa; and the sputtering time in the range of 1-500 min.

M element in the MN is Ti, V, Ta, Mo, or the other one or more of transition metal elements. The composition of the MN thin film is influenced by many factors such as preparation facilities and purities of the used gases, targets, and precursors, etc, leading to the film containing O, Cl, and other impurity elements in addition to the M and N elements. The total atomic percentage of M and N elements in the current collector film with low resistivity is more than 80%; and the total atomic percentage of M and N elements in the electrode film with high resistivity is more than 50%.

The traditional thin film deposition techniques include physical vapor deposition (PVD), such as vacuum evaporation, sputtering and arc plasma plating.

The present invention can also use the chemical vapor deposition (CVD) or atomic layer deposition (ALD) methods to deposit the MN current collector/electrode materials on the cleaned substrate surface.

Step 3: Preparation of supercapacitor.

The MN current collector/electrode materials prepared in step 2 will be used as the anode and cathode of the supercapacitor, and the electrolyte material will be added to prepare the symmetrical or asymmetric structure supercapacitors. The supercapacitor can be constructed as a sandwich structure, a planar interdigitated structure, or a 3D nanostructure, using an electrochemical characterization platform to test the electrochemical performance.

The electrolyte materials can be water-based, organic, ionic liquid, and gel, etc.

The transition metal nitride based current collector and electrode materials and their preparation methodology have a high application value in the field of supercapacitors. Compared with other manufacturing techniques, this preparation methodology is simple and easy to operate, low cost, and has many selections of film deposition technologies, leading to good feasibility and practicality.

The advantages of this invention are as follows: It provides a type of supercapacitor with both the current collector and electrode materials based on transition metal nitride and its preparation methodology, which overcomes the disadvantages of complex operation procedures and high cost encountered in the traditional preparation technologies. It can solve the problems caused by lattice mismatch and difference in the thermal expansion coefficients of heterogeneous current collector and electrode materials, including poor adhesion, delamination, cracking and large contact resistance.

### DESCRIPTION OF THE DRAWINGS

FIG. 1 is a flow chart of the preparation of current collector and electrode materials based on transition metal nitride.

FIG. 2(a) shows cyclic voltammogram curves of TiN single electrode prepared in comparative example 1. FIG. 2(b) shows cyclic voltammetry curves of the TiN electrode grown on TiN current collector both prepared by reactive magnetron sputtering in the implementation example 1. FIG. 2(c), shows the specific capacitances measured at different scan rates are compared for the electrodes described in FIG. 2(a) and FIG. 2(b).

FIG. 3(a) shows cyclic voltammogram curves of VN single electrode prepared in comparative example 2. FIG. 3(b) shows cyclic voltammetry curves of the VN electrode grown on VN current collector both prepared by reactive magnetron sputtering in the implementation example 7. FIG. 3(c) shows the specific capacitances measured at different scan rates are compared for the electrodes described in FIG. 3(a) and FIG. 3(b).

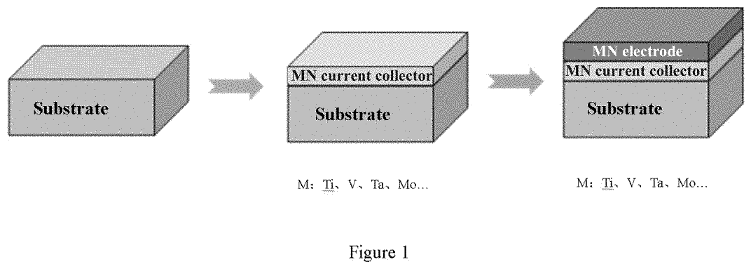

### DETAILED DESCRIPTION

In order to make the objectives, technical solutions and advantages of the present invention clearer, the following describes the operation process of the present invention in further detail with reference to the accompanying drawings and specific examples. It should be noted that the specific examples described here are only used to explain the present invention, and the illustrations are for illustrative purposes, and are not intended to limit the scope of the present invention.

### Comparative Example 1

In this example, the single crystalline silicon was used as a substrate, and the substrate was subjected to a standard RCA cleaning technique in the semiconductor industry. The DC reactive magnetron sputtering was used to deposit a layer of the porous TiN electrode with the thickness of 240 nm and the resistivity of 2800 μΩ·cm. The titanium metal was used as the target, and the distance between the target and substrate was set as 20 mm. The sputtering was continued for 30 min, with the process parameters of Ar:N₂=10:1 sccm, sputtering power of 100 W, substrate temperature of 400° C., and working pressure of 0.4 Pa. The cyclic voltammetry curves were tested using a three-electrode test system of an electrochemical workstation, where the TiN was used as the working electrode, a platinum plate used as the counter electrode, the Ag\AgCl was used as a reference electrode, and the KCl solution was used as an electrolyte.

### Comparative Example 2

In this example, the single crystalline silicon was used as the substrate, and the substrate was subjected to a standard RCA cleaning technique in the semiconductor industry. The DC reactive magnetron sputtering was used to deposit a layer of the porous VN electrode with the thickness of 280 nm and the resistivity of 3000 μΩ·cm. The vanadium metal was used as the target, and the distance between the target and substrate was set as 40 mm. The sputtering was continued for 30 min, with the process parameters of Ar:N₂=15:1 sccm, sputtering power of 200 W, substrate temperature of 300° C., and working pressure of 0.4 Pa. The cyclic voltammetry curves were tested using a three-electrode test system of an electrochemical workstation, where the VN was used as the working electrode, a platinum plate used as the counter electrode, the Ag\AgCl was used as a reference electrode, and the KOH solution was used as an electrolyte.

### Implementation Example 1

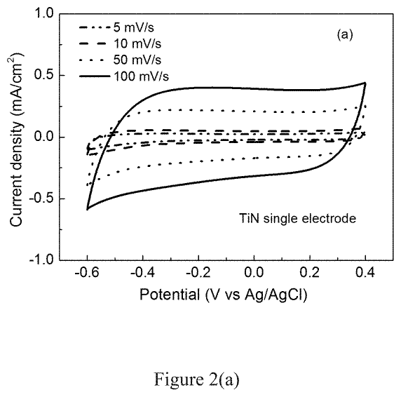

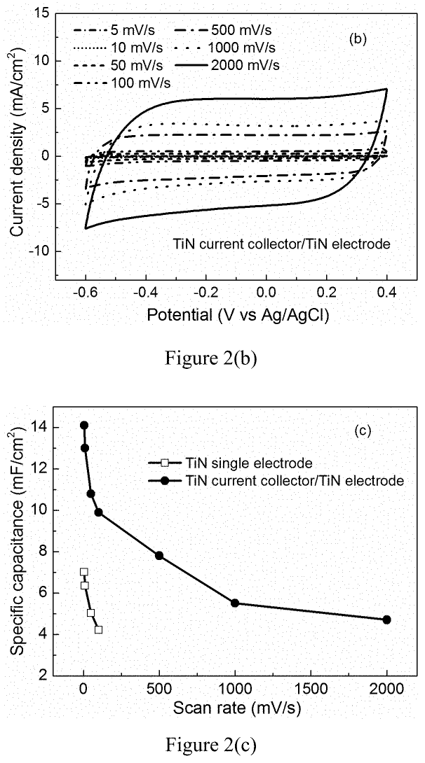

In this example, the single crystalline silicon was used as the substrate, and the substrate was subjected to a standard RCA cleaning technique in the semiconductor industry. The DC reactive magnetron sputtering was used to deposit a smooth and dense TiN current collector with the thickness of 38 nm and the resistivity of 108 μΩ·cm. The titanium metal was used as the target, and the distance between the target and substrate was set as 20 mm. The sputtering was continued for 10 min, with the process parameters of Ar:N₂=10:1 sccm, sputtering power of 100 W, substrate temperature of 400° C., working pressure of 0.2 Pa and substrate bias of −50 V. Then, a layer of porous TiN electrode with a thickness of 240 nm and resistivity of 2800 μΩ·cm were grown continuously on the current collector. The distance between the target and substrate was set as 20 mm. The sputtering was continued for 30 min, with the process parameters of Ar:N₂=10:1 sccm, sputtering power of 100 W, substrate temperature of 400° C., and working pressure of 0.4 Pa. The cyclic voltammetry curves were tested using a three-electrode test system of an electrochemical workstation, where the TiN was used as the working electrode, a platinum plate used as the counter electrode, the Ag\AgCl was used as a reference electrode, and the KCl solution was used as an electrolyte. As can be seen from FIG. 2(b), the CV curves exhibit a nearly symmetrical rectangular shape at high scan rate, indicating the low internal resistance and good rate performance of the TiN electrode. Compared to the high-resistivity TiN electrode in comparative example 1, the specific capacitance of the prepared TiN current collector/electrode increased from the original 7.1 mF/cm² to 14.2 mF/cm², and the highest scan rate of maintaining the capacitive characteristic of the CV curves increased from 100 mV/s to 2000 mV/s.

### Implementation Example 2

In this example, the single crystalline silicon was used as the substrate, and the substrate was subjected to a standard RCA cleaning technique in the semiconductor industry. The DC reactive magnetron sputtering was used to deposit a smooth and dense TiN current collector with the thickness of 30 nm and the resistivity of 28 μΩ·cm. The titanium metal was used as the target, and the distance between the target and substrate was set as 10 mm. The sputtering was continued for 1 min, with the process parameters of Ar:N₂=20:1 sccm, sputtering power of 200 W, substrate temperature of 300° C., working pressure of 0.2 Pa and substrate bias of −100 V. Then, a layer of porous TiN electrode with a thickness of 240 nm and resistivity of 2800 μΩ·cm were grown continuously on the current collector. The distance between the target and substrate was set as 10 mm. The sputtering was continued for 10 min, with the process parameters of Ar:N₂=20:1 sccm, sputtering power of 100 W, substrate temperature of 400° C., and working pressure of 0.4 Pa. The cyclic voltammetry curves were tested using a three-electrode test system of an electrochemical workstation, where the TiN was used as the working electrode, a platinum plate used as the counter electrode, the Ag\AgCl was used as a reference electrode, and the KCl solution was used as an electrolyte.

### Implementation Example 3

In this example, the single crystalline silicon was used as the substrate, and the substrate was subjected to a standard RCA cleaning technique in the semiconductor industry. The RF reactive magnetron sputtering was used to deposit a smooth and dense VN current collector with the thickness of 790 nm and the resistivity of 188 μΩ·cm. The vanadium metal was used as the target, and the distance between the target and substrate was set as 50 mm. The sputtering was continued for 100 min, with the process parameters of Ar:N₂=20:3 sccm, sputtering power of 150 W, substrate temperature of 200° C., working pressure of 0.6 Pa and substrate bias of −150 V. Then, a layer of porous VN electrode with a thickness of 970 nm and resistivity of 6600 μΩ·cm were grown continuously on the current collector. The distance between the target and substrate was set as 50 mm. The sputtering was continued for 100 min, with the process parameters of Ar:N₂=20:3 sccm, sputtering power of 150 W, substrate temperature of 200° C., and working pressure of 0.6 Pa. The cyclic voltammetry curves were tested using a three-electrode test system of an electrochemical workstation, where the VN was used as the working electrode, a platinum plate used as the counter electrode, the Ag\AgCl was used as a reference electrode, and the KOH solution was used as an electrolyte.

### Implementation Example 4

In this example, the single crystalline silicon was used as the substrate, and the substrate was subjected to a standard RCA cleaning technique in the semiconductor industry. The RF reactive magnetron sputtering was used to deposit a smooth and dense VN current collector with the thickness of 1490 nm and the resistivity of 258 μΩ·cm. The vanadium metal was used as the target, and the distance between the target and substrate was set as 50 mm. The sputtering was continued for 200 min, with the process parameters of Ar:N₂=50:8 sccm, sputtering power of 400 W, substrate temperature of 200° C., working pressure of 0.9 Pa and substrate bias of −250 V. Then, a layer of porous VN electrode with a thickness of 1840 nm and resistivity of 9500 μΩ·cm were grown continuously on the current collector. The distance between the target and substrate was set as 60 mm. The sputtering was continued for 200 min, with the process parameters of Ar:N₂=20:1.5 sccm, sputtering power of 400 W, substrate temperature of 100° C., and working pressure of 0.8 Pa. The cyclic voltammetry curves were tested using a three-electrode test system of an electrochemical workstation, where the VN was used as the working electrode, a platinum plate used as the counter electrode, the Ag\AgCl was used as a reference electrode, and the KOH solution was used as an electrolyte.

### Implementation Example 5

In this example, the single crystalline silicon was used as the substrate, and the substrate was subjected to a standard RCA cleaning technique in the semiconductor industry. The RF reactive magnetron sputtering was used to deposit a smooth and dense TiN current collector with the thickness of 5000 nm and the resistivity of 328 μΩ·cm. The titanium metal was used as the target, and the distance between the target and substrate was set as 30 mm. The sputtering was continued for 300 min, with the process parameters of Ar:N₂=30:2 sccm, sputtering power of 300 W, substrate temperature of RT, working pressure of 1.5 Pa and substrate bias of −400 V. Then, a layer of porous TiN electrode with a thickness of 44 nm and resistivity of 1010 μΩ·cm were grown continuously on the current collector. The distance between the target and substrate was set as 100 mm. The sputtering was continued for 1 min, with the process parameters of Ar:N₂=30:2 sccm, sputtering power of 300 W, substrate temperature of RT, and working pressure of 1.5 Pa. The cyclic voltammetry curves were tested using a three-electrode test system of an electrochemical workstation, where the TiN was used as the working electrode, a platinum plate used as the counter electrode, the Ag\AgCl was used as a reference electrode, and the NaCl solution was used as an electrolyte.

### Implementation Example 6

In this example, the single crystalline silicon was used as the substrate, and the substrate was subjected to a standard RCA cleaning technique in the semiconductor industry. The RF reactive magnetron sputtering was used to deposit a smooth and dense TiN current collector with the thickness of 2400 nm and the resistivity of 88 μΩ·cm. The titanium metal was used as the target, and the distance between the target and substrate was set as 100 mm. The sputtering was continued for 500 min, with the process parameters of Ar:N₂=60:10 sccm, sputtering power of 200 W, substrate temperature of RT, working pressure of 1.5 Pa and substrate bias of −400 V. Then, the RF reactive magnetron sputtering was used to deposit a porous 3D nanostructure VN electrode on the TiN current collector with the thickness of 5000 nm and the resistivity of 6200 μΩ·cm. The vanadium metal was used as the target, and the distance between the target and substrate was set as 20 mm. The sputtering was continued for 500 min, with the process parameters of Ar:N₂=60:1 sccm, sputtering power of 300 W, substrate temperature of 300° C., and working pressure of 0.5 Pa. The cyclic voltammetry curves were tested using a three-electrode test system of an electrochemical workstation, where the TiN current collector/VN electrode was used as the working electrode, a platinum plate used as the counter electrode, the Ag\AgCl was used as a reference electrode, and the NaCl solution was used as an electrolyte.

### Implementation Example 7

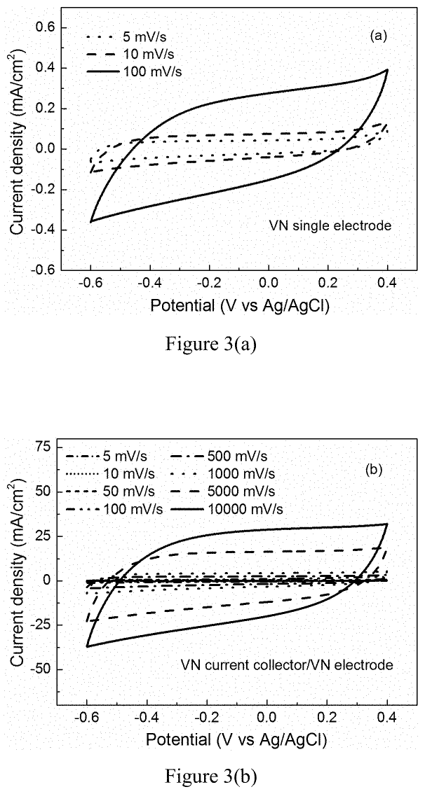

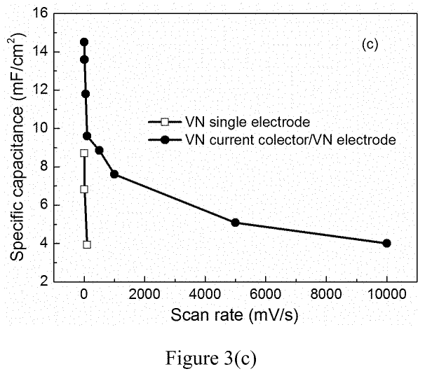

In this example, the single crystalline silicon was used as the substrate, and the substrate was subjected to a standard RCA cleaning technique in the semiconductor industry. The DC reactive magnetron sputtering was used to deposit a smooth and dense VN current collector with the thickness of 25 nm and the resistivity of 100 μΩ·cm. The vanadium metal was used as the target, and the distance between the target and substrate was set as 30 mm. The sputtering was continued for 10 min, with the process parameters of Ar:N₂=10:1 sccm, sputtering power of 100 W, substrate temperature of 400° C., working pressure of 0.2 Pa and substrate bias of −50 V. Then, a layer of porous VN electrode with a thickness of 280 nm and resistivity of 3000 μΩ·cm were grown continuously on the current collector. The distance between the target and substrate was set as 40 mm. The sputtering was continued for 30 min, with the process parameters of Ar:N₂=15:1 sccm, sputtering power of 200 W, substrate temperature of 300° C., and working pressure of 0.4 Pa. The cyclic voltammetry curves were tested using a three-electrode test system of an electrochemical workstation, where the VN was used as the working electrode, a platinum plate used as the counter electrode, the Ag\AgCl was used as a reference electrode, and the KOH solution was used as an electrolyte. As can be seen from FIG. 3, the CV curves exhibit a nearly symmetrical rectangular shape at high scan rate, indicating the low internal resistance and good rate performance of the VN electrode. Compared to the high-resistivity VN electrode in comparative example 2, the specific capacitance of the prepared VN current collector/electrode increased from the original 8.7 mF/cm² to 14.5 mF/cm²; the highest scan rate of maintaining the capacitive characteristic of the CV curves increased from the original 100 mV/s to 10000 mV/s.

### Implementation Example 8

In this example, the single crystalline silicon substrate was used as the substrate, and the substrate was subjected to a standard RCA cleaning technique in the semiconductor industry. The atomic layer deposition was used to deposit a smooth and dense TiN current collector with the thickness of 10 nm and the resistivity of 120 μΩ·cm. The TiCl₄ and NH₃ were used as precursors, with the substrate temperature of 400° C., the carrier gas of N₂, and the deposition of 500 cycles. Then, the deposition was continued for 5000 cycles, with substrate temperature of 300° C. A layer of porous TiN electrode with a thickness of 100 nm and resistivity of 1500 μΩ·cm were grown on the current collector. Sandwiched capacitors were fabricated using PVA/KCl gel electrolyte and TiN current collector/electrode materials. The cyclic voltammetry curves were tested by the two-electrode test system of an electrochemical workstation.

### Implementation Example 9

In this example, the single crystalline silicon substrate was used as the substrate, and the substrate was subjected to a standard RCA cleaning technique in the semiconductor industry. The chemical vapor deposition was used to deposit a smooth and dense TaN current collector with the thickness of 116 nm and the resistivity of 140 μΩ·cm. The Ta(NEt₂)₅ was used as precursor, with the substrate temperature of 400° C., the carrier gas of N₂, and the deposition of 5 min. Then, the deposition was continued for 20 min, with substrate temperature of 250° C. A layer of porous TaN electrode with a thickness of 402 nm and resistivity of 6000 μΩ·cm were grown on the current collector. The cyclic voltammetry curves were tested using a three-electrode test system of an electrochemical workstation, where the TaN was used as the working electrode, a platinum plate used as the counter electrode, the Ag\AgCl was used as a reference electrode, and the NaCl solution was used as an electrolyte.

### Implementation Example 10

In this example, the single crystalline silicon was used as the substrate, and the substrate was subjected to a standard RCA cleaning technique in the semiconductor industry. The DC reactive magnetron sputtering was used to deposit a smooth and dense MoN current collector with the thickness of 86 nm and the resistivity of 120 μΩ·cm. The molybdenum metal was used as the target, and the distance between the target and substrate was set as 60 mm. The sputtering was continued for 20 min, with the process parameters of Ar:N₂=40:4 sccm, sputtering power of 200 W, substrate temperature of RT, working pressure of 1.1 Pa and substrate bias of −100 V. Then, a layer of porous MoN electrode with a thickness of 462 nm and resistivity of 5000 μΩ·cm were grown continuously on the current collector. The distance between the target and substrate was set as 60 mm. The sputtering was continued for 60 min, with the process parameters of Ar:N₂=20:1 sccm, sputtering power of 200 W, substrate temperature of 200° C., and working pressure of 0.6 Pa. The cyclic voltammetry curves were tested using a three-electrode test system of an electrochemical workstation, where the MoN was used as the working electrode, a platinum plate used as the counter electrode, the Ag\AgCl was used as a reference electrode, and the NaCl solution was used as an electrolyte.

### Implementation Example 11

In this example, the single crystalline silicon was used as the substrate, and the substrate was subjected to a standard RCA cleaning technique in the semiconductor industry. The DC reactive magnetron sputtering was used to deposit a smooth and dense HfN current collector with the thickness of 46 nm and the resistivity of 110 μΩ·cm. The hafnium metal was used as the target, and the distance between the target and substrate was set as 70 mm. The sputtering was continued for 10 min, with the process parameters of Ar:N₂=50:6 sccm, sputtering power of 200 W, substrate temperature of RT, working pressure of 0.5 Pa and substrate bias of −100 V. Then, a layer of porous HfN electrode with a thickness of 562 nm and resistivity of 5500 μΩ·cm were grown continuously on the current collector. The distance between the target and substrate was set as 60 mm. The sputtering was continued for 60 min, with the process parameters of Ar:N₂=20:2 sccm, sputtering power of 200 W, substrate temperature of 100° C., and working pressure of 0.9 Pa. The HfN planar interdigitated capacitors were prepared by the semiconductor photolithography technology. The NaCl solution used as an electrolyte, the cyclic voltammetry curves were tested by an electrochemical workstation.

The above-mentioned examples only express the embodiments of this invention, but they should not be understood as a limitation of the scope of the invention. It should be pointed out that for those skilled in the art, without departing from the concept of the present invention, some modifications and improvements can also be made, which belong to the protection scope of the present invention.

1-4. (canceled)

5. A preparation method of the supercapacitor with both current collector and electrode based on transition metal nitride, wherein the preparation method comprises the following steps:
step 1: substrates are cleaned to remove impurities and contaminations on the surface; the substrate material is one of Si, Ge and the other III/V semiconductor materials, glass or flexible polymer substrate;
step 2: thin film deposition technique is used to deposit the transition metal nitride MN current collectors/electrodes on the surface of substrate materials;
first, a layer of smooth MN thin film with high density and conductivity (low resistivity) is deposited as a current collector on the cleaned substrates in step 1 by physical vapor deposition; then deposition process parameters are adjusted to tailor the mechanisms of surface atomic diffusion, nucleation and growth of the thin film, whereby a layer of rough and porous MN thin film with low conductivity and high resistivity is grown continuously on the current collector as an electrode; MN current collector/electrode materials are deposited on the surface of the substrate;
the thickness of the MN thin film for the current collector is 10-5000 nm, with the resistivity less than 500 μΩ·cm; the thickness of the MN thin film for the electrode is 10-5000 nm, with the resistivity higher than 1000 μΩ·cm;
the deposition process parameters for current collector are as follows: the distance between the target and substrate in the range of 10-100 mm; Ar:N₂=(10-60):(1-10) sccm; the sputtering power in the range of 100-400 W; the substrate temperature ranged from room temperature to 400° C.; the working pressure in the range of 0.2-1.5 Pa; the bias voltage applied on substrate ranged from −50 to −400 V; and the sputtering time in the range of 1-500 min;
the deposition process parameters for electrode are as follows: the distance between the target and substrate in the range of 10-100 mm; Ar:N₂=(10-60):(1-10) sccm; the sputtering power in the range of 100-400 W; the substrate temperature ranged from room temperature to 400° C.; the working pressure in the range of: 0.4-1.5 Pa; and the sputtering time in the range of 1-500 min;
step 3: preparation of supercapacitors;
the MN current collector/electrode materials prepared in step 2 are used as the anode and cathode of the supercapacitor, and electrolyte material are added to prepare the supercapacitors; the supercapacitor is constructed as a sandwich structure, a planar interdigitated structure, or a 3D nanostructure; the positive and negative terminals of the supercapacitor is symmetrically or asymmetrically constructed; for the symmetrical structure, both the positive and negative terminals of the supercapacitor use the same kind of transition metal nitride (MN) material as current collector/electrode; for the asymmetric structure, the positive and negative terminals of the supercapacitor use different kinds of transition metal nitrides as current collector/electrode materials, one terminal uses transition MN material as current collector/electrode, the other terminal uses other conventional electrode and current collector materials of supercapacitors; M element in the MN is Ti, V, Ta or Mo;
the conventional electrode materials of supercapacitors are carbon-/silicon-based materials, metal oxides or conductive polymers; the conventional current collector materials of supercapacitors are gold, copper, titanium, platinum or nickel foam.

6. The preparation method of supercapacitors with both current collector and electrode based on transition metal nitride according to claim 5, in the step 2, chemical vapor deposition (CVD) method or atomic layer deposition (ALD) method is used to deposit the MN current collector/electrode materials on the cleaned substrate surface.

7. The preparation method of supercapacitors with both current collector and electrode based on transition metal nitride according to claim 5, the MN current collector/electrode materials contain the O, Cl or impurity elements in addition to M and N elements; the total atomic percentage of M and N elements in the current collector film with low resistivity is more than 80%; and the total atomic percentage of M and N elements in the electrode film with high resistivity is more than 50%.

8. The preparation method of supercapacitors with both current collector and electrode based on transition metal nitride according to claim 5, physical vapor deposition (PVD) includes vacuum evaporation, sputtering and arc plasma plating.

9. The preparation method of supercapacitors with both current collector and electrode based on transition metal nitride according to claim 5, the III/V semiconductor is gallium arsenide; the flexible polymer substrate materials are polyethylene terephthalate (PET), polyimide (PI).
